(19) United States
(12) Patent Application Publication
(10) Pub. No.: US 2014/0268508 A1
(43) Pub. Date: Sep. 18, 2014

(54) FRAMEWORK FOR TAILORED PERSONAL ELECTRONICS

(71) Applicant: DAVID CZARNECKI, (US)

(72) Inventors: DAVID CZARNECKI, Seattle, WA (US); Juan Felipe Sadder, Seattle, WA (US)

(21) Appl. No.: 13/797,780

(22) Filed: Mar. 12, 2013

(51) Int. Cl. H05K 7/00

(52) U.S. Cl. CPC H05K 7/00
USPC 361/679.01; 428/34.1

(57) ABSTRACT

One embodiment of the practical framework for production of apparel articles incorporating electronic devices such as wired speakers. This framework securely locates the desired electronic (1) and applique elements (9, 10). The materials of which the substrate (3, 4, 6, 7) is comprised possess distinct qualities enabling it to be molded, formed, cut, sewn, mechanically fastened, and adhered to. In this way the substrate (3, 4, 6, 7) can be imparted with distinct features (3a, 3b, 3c, 4a, etc. . . . ). The features can provide for specific dimensional requirements and structural conditions. Some of these substrate features can be an acoustic chamber for a speaker (4a) or a detailed shape on which to fasten decorative materials (3a). This combination of features and qualities make the framework uniquely provide for any number of varied designs.

### CROSS-REFERENCE FOR RELATED APPLICATIONS

This application claims the benefit of provisional patent application Ser. No. 61/609,907, filed on 2012 Mar. 12 by present inventors

### FEDERALLY SPONSORED RESEARCH

Not Applicable

### SEQUENCE LISTING

Not Applicable

### BACKGROUND

1. Field

This relates to electronics, specifically to the construction of enclosures for electronics.

2. Prior Art

Currently, enclosures for electronics lack the tactile qualities and aesthetic diversity of apparel items and other soft, goods. This fact is due in great part to broad technical differences between the makers of consumer electronics and the makers of soft goods. Hard plastic shells are typical of consumer electronics. The qualities of a hard plastic shell are in direct conflict with the crafted nature of soft goods. Soft goods use a patchwork of several materials that are sewn, glued and otherwise fastened to each other achieving form, function and aesthetic. The techniques used by soft goods manufacturers require materials that facilitate these methods. Hard shells of plastic and other materials can not accommodate such methods. Consumers are outfitted with many everyday personal electronics. Soft goods and, apparel makers have long sought means of crafting portable electronics with adequate tactile qualities and aesthetic diversity.

U.S. Pat. No. 7,519,192 to Laycock (2009) and U.S. Pat. No. 8,107,653 to Wolfe (2012) discloses methods for permanently setting headphones into a garment. These methods are narrow and only aim to feed wires and connectors through established garments offering no solutions for integrating various and diverse electronic components into an enclosure. U.S. Pat. No. 7,035,422 (2006) to Wiener arranges a complex sound system into a highly specialized garment that fails to provide soft good and apparel makers a platform for producing anything but this specialized device. U.S. Pat. No. 6,502,248 to Legette (2003) describes a method to impart desirable aesthetic and mechanical properties to ear warmers but fails to expand the invention to accommodate purchase points or internal volumes for any type of electronic component.

U.S. Pat. No. 7,673,528 to Yoon (2010) demonstrates a method for the setting sensors on a flexible substrate with embedded conductor lines connecting the sensors. The substrate is flat and flexible but in no way offers methods to enclose the sensors. There is no provision for manufacturability employing methods common to the soft good and apparel industry.

### SUMMARY

Alcombination of substrate, the substrate form features, electronic components, and applique make up the versatile framework.

### DRAWINGS

### Figures

FIG. 1 is an exploded perspective view taken from the users left side.

FIG. 2 is a un-exploded perspective view taken from the users left side.

FIG. 3 is section view “AA” from FIG. 4.

FIG. 4 is a perspective view of the completed embodiment taken from the users left side.

### REFERENCE NUMERALS

1. Driver
2. Chord
3. Substrate Bridge.
   a Design Specific Form
   b. Recess I protrusion
   c. Hole
4. Substrate Chamber
   a. Open Chamber
   b. Flange
   c. Channel
   5. Structural Rod
6. Substrate Grill
   a. Flat Cut Shape
7. Substrate Baffle
8. Rivet
9. Applique One
   a. Sewed Seams
10. Applique Two

### DETAILED DESCRIPTION OF FIRST EMBODIMENT

FIG. 1 is an exploded perspective view taken from the users left side illustrating a headphone embodiment of the framework. Substrate elements: 3,4,6,7. Formed features: 3a, 3b, 3c, 4a, 4b, 4c, 6a. Electronic components: 1,2. Structural components 5. Mechanical fasteners: 8. The appliques: 9,10 and sewed seams: 9a.

FIG. 2 is a perspective view taken from the users left side and illustrates the Headphone embodiment assembled but without the applique 9,10 or the sewed seams 9a.

FIG. 3 is section view “AA” from FIG. 4 illustrating how substrate elements and applique can be joined via a standard sewing operation. Some other similar operations are gluing or riveting.

FIG. 4 is a perspective view taken from the users left side and illustrates the Headphone embodiment achieved with the described framework. Carefully planned sewed seams 9a and thoughtfully selected appliques 9,10 are the final touches to complete the headphone embodiment.

### Operation

In operation the user of the framework produces the substrate elements 3,4 6,7 with various forming operations performed on materials like EVA or TPU. The forming operations produce features 3a, 3b, 3c, 4a, 4b, 4c, 6a along with the general forms defined by the drawings. The user then combines the substrate elements 3,4,6,7 to the other elements by way of sewing gluing and/or mechanically fastening. The Drivers 1 are attached to the Substrate Baffle 7 by the operator through gluing. This combination of the Substrate Baffle 7 and the Drivers 1 are then sewn to the Substrate Chamber 4. The Chord 2 is woven through holes and Channel 4c in the Substrates and connected to terminals on the Drivers 1. Structural Rod 6 is slid into place and fastened to the Substrate Bridge 3 with Rivets 8 through Holes 3c. The applique 9,10 is sewn 9a to the substrate elements 3,4,6,7 achieving the desired tactile qualities and aesthetic diversity. This completes the headphones as a tailored personal electronic.

### Alternative Embodiments

There are various possibilities with regard to the relative shape and mechanical features formed by the substrate elements like 3, 4, 6, and 7 in FIG. 2. The substrate elements can take the forms needed to accommodate any number of mechanical needs as illustrated in FIG. 1 and elaborated as follows:

(a) Vents for the release of heat or sound like Substrate Chamber 4 with feature 4a.

(b) Structural geometry for added strength like feature 3b on Substrate Bridge 3.

(c) Substrate elements like Substrate Baffle 7 offer purchase points for the attachment of electronic components such as a Driver 10

(d) The Substrate elements can be formed to incase a variety of electronic components such a microphone or a flash light. This flexibilty offers a platform for the production of various electronic devices in a tailored inclosure.

(e) The Substrate elements provide attachment points for other types of components such as a Structural Rod 5 or a Chord 2 adding further versatility to the framework.

(f) Forms such as feature 3a to provide aesthetic shapes or functional elements like the brim on a hat.

### Advantages

From the description above a number of advantages and various embodiments of the framework for the tailored personal electronics become evident:

(a) To provide viable means of tailoring and constructing personal electronics.

(b) To offer compatibility with established production methods and techniques of the soft good and apparel industry.

(c) To achieve the resulting personal electronics with adequate tactile qualities and aesthetic diversity.

(d) Leveraging the modular nature of electronics.

Accordingly, the reader will see that the framework for tailored personal electronics can be used by the soft goods and apparel industry to embody various personal electronic designs. The resulting personal electronics are produced inexpensively by leveraging established production methods and techniques of the soft good and apparel industry. By means of the applique 9, and 10, the framework allows personal electronics to take on the tactile qualities and aesthetic diversity previously reserved for soft good and apparel items. This applique method is not possible with traditional enclosures. Many electronics are standardizes allowing this framework to leverage speakers, lights, etc like buttons or badges that are typical components in a garments.

Although the description above contains many specificities, these should not be construed as limiting the scope of embodiments but as merely providing illustrations for one of the presently preferred embodiments. For example the substrate-bridge can form a visor; the substrate-chamber can be cylindrical and formed to house a light and not a driver.

Thus the scope of the embodiments should be determined by the appended claims and their legal equivalents, rather than by the examples given.

1. A framework for the production of tailored electronics, comprising:
a. substrate elements of materials compatible with common soft goods production techniques such molding, forming, cutting, sewing, mechanically fastening, and adhesives;
b. The substrate elements are produced to provide attachment and connection points as well as housings for various electronic, mechanical, structural, and aesthetic components;
c. whereby a user with said framework and use of common soft goods production techniques can easily tailor varied designs to utilize a multitude of components, and decorative attachments.

2. A tailored electronic constructed with the framework according to claim one:
a. whereby single or various substrate elements and, the substrate features come together for a unique substrate design;
b. The unique substrate design can then be finished with Applique materials in various colors, textures and patterns;
c. or the unique substrate design can remain without the applique to expose intricate features of the unique substrate design.

3. A tailored electronic constructed with the framework according to claim one:
a. whereby substrate elements can be designed with features that serve strictly as mechanical, structural or aesthetic elements;
b. substrate elements can reside completely or partially inside a grater enclosure.
